(19) United States
(12) Patent Application Publication
(10) Pub. No.: US 2026/0303080 A1
(43) Pub. Date: Oct. 1, 2026

(54) METHOD AND APPARATUS FOR CONTROLLING ADAPTIVE CHARGE-RECOVERY IN SWITCHING REGULATOR

(71) Applicant: Airoha Technology Corp., Hsinchu City (TW)

(72) Inventors: Chun-Kai Chiu, Hsinchu County (TW); Chen-Yu Wang, Hsinchu County (TW)

(73) Assignee: Airoha Technology Corp., Hsinchu City (TW)

(21) Appl. No.: 19/458,908

(22) Filed: Jan. 25, 2026

Related U.S. Application Data
(60) Provisional application No. 63/777,701, filed on Mar. 26, 2025.

(51) Int. Cl. H03K 17/042; H02M 3/157; H03K 7/08

(52) U.S. Cl. CPC H03K 17/04206; H03K 7/08; H02M 3/157; H03K 2217/0063; H03K 2217/0072

(57) ABSTRACT

A controller circuit of a switching regulator includes a constant on-time (COT) setting circuit and a decision circuit. The COT setting circuit adjusts a COT control setting adaptively, wherein an on-time of a high-side power switch of the switching regulator depends on the COT control setting. The decision circuit enables a control scheme of periodically triggering a regulation operation of an output voltage of the switching regulator during a period in which the COT control setting is assigned a minimum COT control value allowed by the switching regulator, wherein during the period, a turn-off time of a low-side power switch of the switching regulator depends on a comparison between a feedback voltage and a first reference voltage, where the feedback voltage is derived from the output voltage.

### CROSS REFERENCE TO RELATED APPLICATIONS

This application claims the benefit of U.S. Provisional Application No. 63/777,701, filed on Mar. 26, 2025. The content of the application is incorporated herein by reference.

### BACKGROUND OF THE INVENTION

### 1. Field of the Invention

The present disclosure relates to a switching regulator design, and more particularly, to a method and apparatus for controlling adaptive charge-recovery in a switching regulator.

### 2. Description of the Prior Art

With advanced development in technology, various electronic products have been presented and are widely used in daily life. In general, a switching regulator is required for providing operating power for an electronic product. The switching regulator may be a buck converter that is capable of converting a high direct current (DC) voltage to a low and stable DC voltage for normal operations of the electronic product. The switching regulator may be employed by an audio device such as Bluetooth (BT) earbuds. When an output voltage of the switching regulator is supplied to a light load (or an extremely light load), the switching frequency F_{SW} of the switching regulator is low, and may induce audible power noise that affects user's auditory experience. To keep the switching frequency F_{SW} above the audio frequency band (i.e., F_{SW}>20 KHz) under the light load condition (or the extremely light load condition), a typical solution is adding a dummy load to an output node of the switching regulator. However, the additional dummy load will cause energy loss, resulting in poor efficiency under the light load condition (or the extremely light load condition).

### SUMMARY OF THE INVENTION

One of the objectives of the present disclosure is to provide a method and apparatus for controlling adaptive charge-recovery in a switching regulator.

According to a first aspect of the present invention, an exemplary controller circuit of a switching regulator is disclosed. The exemplary controller circuit includes a constant on-time (COT) setting circuit and a decision circuit. The COT setting circuit is configured to adaptively adjust a COT control setting, wherein an on-time of a high-side power switch of the switching regulator depends on the COT control setting. The decision circuit is configured to enable a control scheme of periodically triggering a regulation operation of an output voltage of the switching regulator during a period in which the COT control setting is assigned a minimum COT control value allowed by the switching regulator, wherein during the period, a turn-off time of a low-side power switch of the switching regulator depends on a comparison between a feedback voltage and a first reference voltage, where the feedback voltage is derived from the output voltage.

According to a second aspect of the present invention, an exemplary method of controlling a switching regulator is disclosed. The exemplary method includes: adaptively adjusting a constant on-time (COT) setting, wherein an on-time of a high-side power switch of the switching regulator depends on the COT control setting; and during a period in which the COT control setting is assigned a minimum COT control value allowed by the switching regulator, enabling a control scheme of periodically triggering a regulation operation of an output voltage of the switching regulator, wherein during the period, a turn-off time of a low-side power switch of the switching regulator depends on a comparison between a feedback voltage and a first reference voltage, where the feedback voltage is derived from the output voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a switching regulator according to an embodiment of the present invention.

FIG. 2 is a diagram illustrating a normal COT regulation operation and a CB-mode regulation operation according to an embodiment of the present invention.

FIG. 3 is a diagram illustrating a PWM-based adaptive adjustment algorithm employed by a controller circuit of a switching regulator according to an embodiment of the present invention.

FIG. 4 is a diagram illustrating a waveform of an output voltage regulated under a CB control scheme according to an embodiment of the present invention.

FIG. 5 is a diagram illustrating a controller circuit of a switching regulator according to an embodiment of the present invention.

FIG. 6 is a flowchart illustrating a method for controlling a switching regulator according to an embodiment of the present invention.

FIG. 7 is a flowchart illustrating a hysteresis-based control method for controlling V_{OUT} regulation according to an embodiment of the present invention.

FIG. 8 is a diagram illustrating a hysteresis behavior of a switching regulator according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

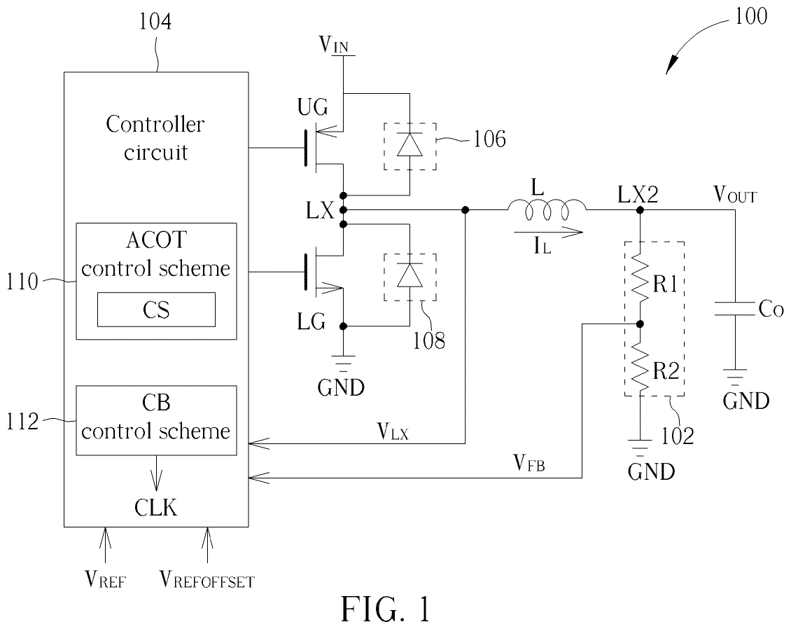

FIG. 1 is a diagram illustrating a switching regulator according to an embodiment of the present invention. The switching regulator 100 is a voltage converter such as a buck converter. In this embodiment, the switching regulator 100 is designed for converting an input voltage V_{IN} into an output voltages V_{OUT} (e.g., V_{OUT}<V_{IN}). The input voltage V_{IN} may be supplied from a power source such as a battery. The output voltage V_{OUT} is supplied to a load device (not shown). The load device may be any electronic device that consumes electricity. The switching regulator (e.g., buck converter) 100 includes an inductor L, a high-side power switch UG, a low-side power switch LG, a feedback circuit 102, an output capacitor C_{O}, and a controller circuit (e.g., buck controller) 104.

The high-side power switch UG may be implemented using a P-channel metal-oxide-semiconductor (PMOS) transistor. The low-side power switch LG may be implemented using an N-channel metal-oxide-semiconductor (NMOS) transistor. Due to inherent characteristics of the PMOS transistor, the high-side power switch UG has a body diode 106 with an anode coupled to a drain terminal and a cathode coupled to a source terminal. Due to inherent characteristics of the NMOS transistor, the low-side power switch LG has a body diode 108 with an anode coupled to a source terminal and a cathode coupled to a drain terminal. The high-side power switch UG and the low-side power switch LG are series-connected between a first voltage node (e.g., input voltage V_{IN}) and a second voltage node (e.g., ground voltage GND). Specifically, the high-side power switch UG is coupled between the first voltage node (e.g., input voltage V_{IN}) and a switching node LX, and the low-side power switch LG is coupled between the switching node LX and the second voltage node (e.g., ground voltage GND). The inductor L has a first end coupled to the switching node LX, and has a second node coupled to a switching node LX2. An inductor current I_{L} flowing through the inductor L is defined to have a positive polarity when the inductor current I_{L} flows in a forward direction LX→LX2 that would transfer energy to the load device. The inductor current I_{L} flowing through the inductor L is defined to have a negative polarity when the inductor current I_{L} flows in a backward direction LX2→LX opposite to the forward direction LX→LX2.

The controller circuit 104 is configured to control an ON/OFF state of each of the high-side power switch UG and the low-side power switch LG for V_{OUT} regulation. The feedback circuit 102 is configured to generate a feedback voltage V_{FB} according to the output voltage V_{OUT} of the switching regulator 100. In this embodiment, the feedback circuit 102 is implemented by a voltage divider with series-connected resistors R1 and R2 between the output voltage V_{OUT} and a reference terminal (e.g., ground voltage GND). The resistance values of the resistors R1 and R2 may be set in accordance with practical requirements. The feedback circuit 102 is configured to perform voltage division upon the output voltage V_{OUT} to generate a divided voltage as the feedback voltage V_{FB}, and provides the feedback voltage V_{FB} to the controller circuit 104. Since the feedback voltage V_{FB} is positively correlated with the output voltage V_{OUT}, the controller circuit 104 is aware of the instant status of the output voltage V_{OUT}. Alternatively, the feedback voltage V_{FB} may be directly set by the output voltage V_{OUT}. To put it simply, the feedback voltage V_{FB} may be set by any voltage signal derived from the output voltage V_{OUT}. The controller circuit 104 may further receive a voltage V_{LX} at the switching node LX.

The switching regulator 100 may be configured to adopt an adaptive constant on-time (ACOT) control scheme under a discontinuous current mode (DCM). In this embodiment, the controller circuit 104 may support a plurality of control schemes, including a typical ACOT control scheme 110 and a proposed charge back (CB) control scheme 112. When the switching regulator 100 operates under a normal mode (e.g., normal COT mode), the ON state of the high-side power switch UG may be triggered based on the feedback voltage V_{FB}

$$( {V}_{FB} = {V}_{OUT} * \frac{R 2}{R 1 + R 2} or {V}_{FB} = {V}_{OUT} ) ,$$

and the OFF state of the low-side power switch LG may be triggered based on the voltage V_{LX}. When the switching regulator 100 operates under proposed CB mode, the ON state of the high-side power switch UG may be periodically triggered based on a fixed clock CLK (e.g., a 35 KHz clock with a 28 us period or a 32 KHz clock with a 31.25 us period), and the OFF state of the low-side power switch LG may be triggered based on the feedback voltage V_{FB}

$$( {V}_{FB} = {V}_{OUT} * \frac{R 2}{R 1 + R 2} or {V}_{FB} = {V}_{OUT} ) .$$

The proposed CB control scheme 112 is enabled when certain criteria are met.

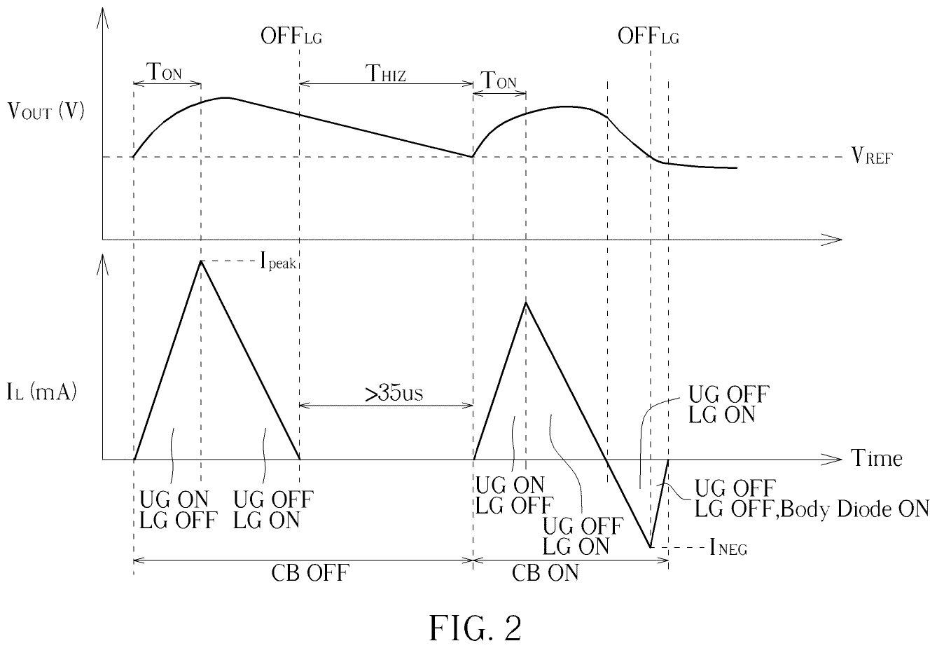

FIG. 2 is a diagram illustrating a normal COT regulation operation and a CB-mode regulation operation according to an embodiment of the present invention. Suppose that the output voltage V_{OUT} is fed back to serve as the feedback voltage V_{FB} needed by the controller circuit (e.g., buck controller) 104. Regarding the normal COT regulation operation, the controller circuit 104 compares the feedback voltage V_{FB} with a reference voltage V_{REF} (which is a target voltage level of the regulator output). When the output voltage V_{OUT} is lower than the reference voltage V_{REF}, the controller circuit 104 turns on the high-side power switch UG to start one regulation operation. The ACOT control scheme 110 has a COT control setting CS which is set to control an on-time T_{ON} of the high-side power switch UG. After the on-time T_{ON} expires, the controller circuit 104 turns off the high-side power switch UG, and turns on the low-side power switch LG. The controller circuit 104 compares the voltage V_{LX} with the ground voltage GND. When the decreasing voltage V_{LX} reaches the ground voltage GND, meaning that the inductor current I_{L} is a zero current (i.e., I_{L}=0 mA), the controller circuit 104 turns off the low-side power switch LG at the turn-off time OFF_{LG} (i.e., the time instant when V_{LX}=0V). Since both of the high-side power switch UG and the low-side power switch LG are turned off and the inductor current I_{L} is a zero current, the switching regulator 100 enters a High-Z (HiZ) state.

The controller circuit 104 checks if the HiZ time T_{HIZ} between a previous regulation operation and a current regulation operation is longer than a threshold value (e.g., 35 us). That is, the controller circuit 104 monitors the HiZ time T_{HIZ} starting from an end of the previous regulation operation. If the HiZ time T_{HIZ} has lasted for a duration exceeding the threshold value (e.g., 35 us), implying that the switching frequency F_{SW} is close to an upper bound of the audio frequency band, the controller circuit 104 may enable the CB control scheme 112 to periodically trigger one CB-mode regulation operation according the fixed clock CLK. For example, the CB-mode regulation operation is triggered once during each period of the fixed clock CLK. It should be noted that the threshold value set by 35 us is for illustrative purposes only, and is not meant to be a limitation of the present invention. The HiZ time T_{HIZ} that reaches the threshold value implies that the switching frequency F_{SW} above the audio frequency band is close to the upper bound (e.g., 20 KHz) of the audio frequency band now. In practice, the setting of the threshold value may depend on actual design considerations.

After the CB control scheme 112 is enabled, the controller circuit 104 turns on the high-side power switch UG to start a current regulation operation (which is a CB-mode regulation operation) following a previous regulation operation (which is a normal COT regulation operation). After the on-time T_{ON} (which is set by the minimum COT control value indicated by the COT control setting CS) expires, the controller circuit 104 turns off the high-side power switch UG, and turns on the low-side power switch LG. The controller circuit 104 compares the feedback voltage V_{FB} with the reference voltage V_{REF}. When the decreasing voltage V_{LX} reaches the ground voltage GND, meaning that the inductor current I_{L} is a zero current (i.e., I_{L}=0 mA), the CB control scheme 112 does not turn off the low-side power switch LG, allowing the inductor current I_{L} to reverse its polarity and increase its magnitude. Specifically, the CB control scheme 112 does not turn off the low-side power switch LG until the output voltage V_{OUT} drops below (or reaches) the reference voltage V_{REF}. The negative inductor current is equal to I_{NEG} at the time the output voltage V_{OUT} reaches the reference voltage V_{REF}. After the low-side power switch LG is turned off, the negative inductor current flows back to the power source (e.g., battery) through the body diode 106 of the high-side power switch UG, thereby returning the excess energy (i.e., excess quantity of electric charge) to the power source (e.g., battery). It should be noted that both of the high-side power switch UG and the low-side power switch LG are turned off by the controller circuit 104, and the body diode 106 of the turned-off high-side power switch UG is forward biased for passing the negative inductor current from the inductor L to the power source (e.g., battery). The switching regulator 100 re-enters the HiZ state after the inductor current I_{L} becomes a zero current (i.e., I_{L}=0 mA) under a condition that both of the high-side power switch UG and the low-side power switch LG are turned off.

It should be noted that the waveforms shown in FIG. 2 are for illustrative purposes only, and are not meant to be limitations of the present invention. In some embodiments of the present invention, the proposed CB control scheme 112 is enabled when certain criteria are met. For example, the switching regulator 100 does not enter the CB mode unless the HiZ time T_{HIZ} between the previous regulation operation and the current regulation operation is longer than the threshold value (e.g., 35 us) and the COT control setting CS is assigned a minimum COT control value (which corresponds to a minimum peak current Iₚₑₐₖ of the inductor L that is allowed by the switching regulator 100 due to hardware limitations). In addition, the proposed CB control scheme 112 is disabled when certain criteria are met. For example, the switching regulator 100 does not leave the CB mode unless the output voltage V_{OUT} reaches a reference voltage V_{REFOFFSET} (V_{REFOFFSET}=V_{REF}−OFFSET) lower than the reference voltage V_{REF} (which is a target voltage level of the regulator output).

Specifically, the COT control setting CS is initialized by a default value such as a maximum COT control value Cot_max (which corresponds to a maximum peak current Iₚₑₐₖ of the inductor L that is allowed by the switching regulator 100 due to hardware limitations). The ACOT control scheme 110 adaptively adjusts the COT control setting CS until the COT control setting CS is assigned the minimum COT control value Cot_min (which corresponds to a minimum peak current Iₚₑₐₖ of the inductor L that is allowed by the switching regulator 100 due to hardware limitations). Since the peak current Iₚₑₐₖ cannot be further reduced to increase the switching frequency F_{SW} under a condition that the COT control setting CS has been assigned the minimum COT control value Cot_min, the present invention proposes enabling the CB control scheme 112 to keep the switching frequency F_{SW} at a higher frequency value (e.g., 32 KHz) above the audio frequency band, and further proposes using a pulse-width modulation (PWM) based adaptive adjustment algorithm for adaptively adjusting charge-recovery of each CB-mode regulation operation under the fixed switching frequency F_{SW}, where the turn-off time OFF_{LG} of the low-side power switch LG is adaptively adjusted based on a comparison between the feedback voltage V_{FB} and the output voltage V_{OUT}.

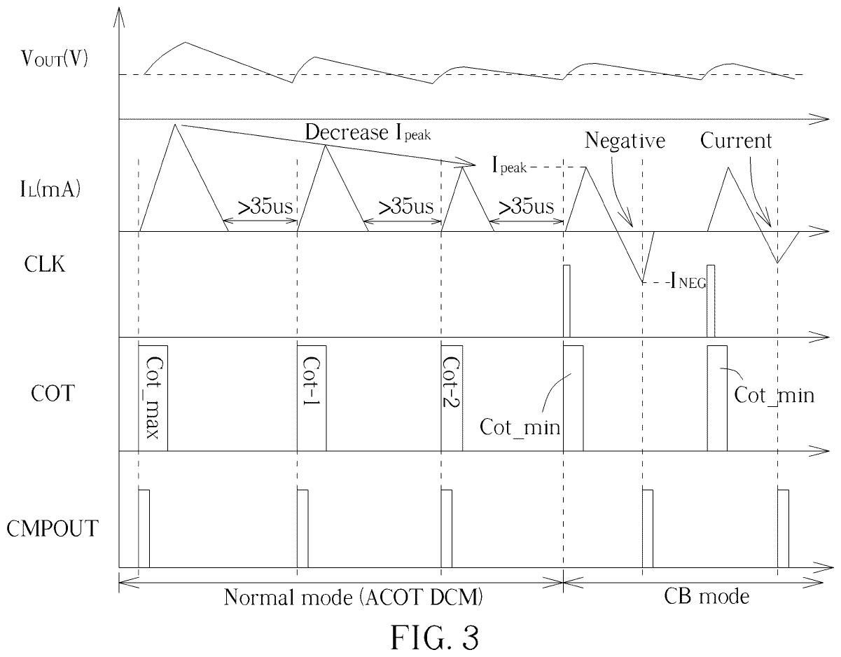

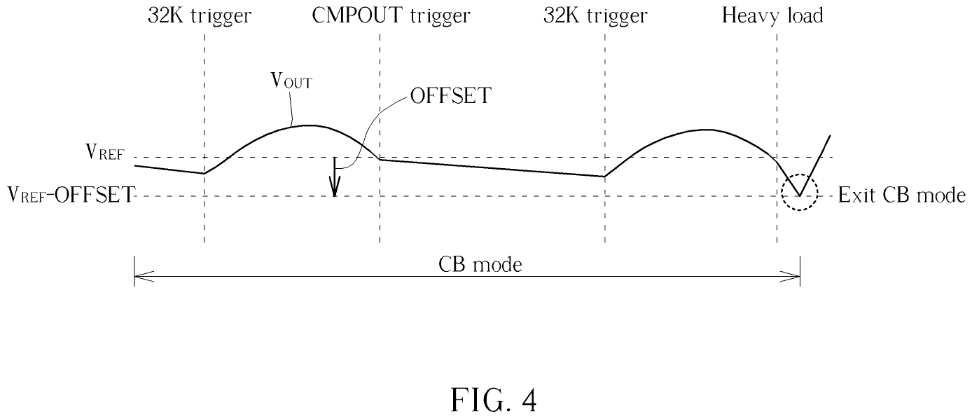

FIG. 3 is a diagram illustrating the PWM-based adaptive adjustment algorithm employed by the controller circuit 104 according to an embodiment of the present invention. When the switching frequency F_{SW} is lower than a threshold value, making the HiZ time longer than 35 us, the positive peak current Iₚₑₐₖ will be reduced by adaptively adjusting (decreasing) the COT control setting CS. One normal-mode regulation operation is triggered by a trigger pulse of the comparator output CMPOUT that is output due to the feedback voltage V_{FB} drops below the reference voltage V_{REF}. Once the positive peak current Iₚₑₐₖ is reduced to its minimum value due to the COT control setting CS assigned with the minimum COT control value Cot_min and the HiZ time is still longer than 35 us, the fixed clock CLK is used by the CB control scheme 112 to periodically trigger the regulation operation of the output voltage V_{OUT} during a period in which the COT control setting CS is assigned with the minimum COT control value Cot_min. The magnitude of the inductor's negative peak current I_{NEG} is set at the time the low-side power switch LG is turned off by a trigger pulse of the comparator output CMPOUT that is output due to the feedback voltage V_{FB} reaching the reference voltage V_{REF}. The inductor's negative peak current I_{NEG} will be adaptively adjusted if the feedback voltage V_{FB} does not drop below the lower reference voltage V_{REFOFFSET} before a next regulation operation is triggered by the fixed clock CLK. As shown in FIG. 4, when the load device suddenly becomes a heavy load requiring large power, the feedback voltage V_{FB} drops below the lower reference voltage V_{REFOFFSET} under the CB mode (which periodically triggers one regulation operation based on the fixed clock CLK), causing the switching regulator 100 to exit the CB mode and re-enter the normal mode (which triggers one regulation operation based on a comparison between the feedback voltage V_{FB} and the output voltage V_{OUT}). Further details of the PWM-based adaptive adjustment algorithm for charge-recovery under the CB mode are described as below with reference to the accompanying drawings.

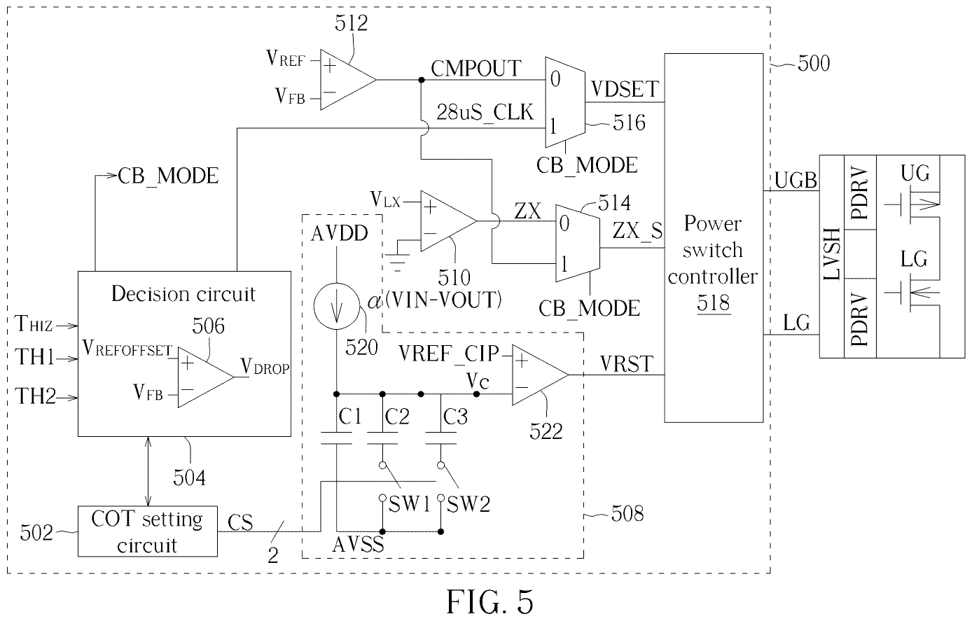

FIG. 5 is a diagram illustrating a controller circuit of a switching regulator according to an embodiment of the present invention. The controller circuit 104 shown in FIG. 1 may be implemented using the controller circuit 500. The controller circuit 500 includes a COT setting circuit 502, a decision circuit 504, an on-time generator 508, comparators 510, 512, multiplexers 514, 516, and a power switch controller 518. The COT setting circuit 502 is configured to adaptively adjust the COT control setting CS, wherein an on-time T_{ON} of the high-side power switch UG of the switching regulator 100 depends on the COT control setting CS. The decision circuit 504 is configured to enable/disable a CB control scheme (i.e., CB mode) of periodically triggering a regulation operation of the output voltage V_{OUT} during a period in which the COT control setting CS is assigned the minimum COT control value Cot_min allowed by the switching regulator 100. Specifically, the decision circuit 504 asserts the control signal CB_MODE (CB_MODE=1) to enable the CB mode, and deasserts the control signal CB_MODE (CB_MODE=0) to disable the CB mode.

In this embodiment, the decision circuit 504 acts as a normal-mode controller and a CB-mode controller. For example, the decision circuit 504 monitors the HiZ time T_{HIZ} between two successive regulation operations to determine whether to instruct the COT setting circuit 502 to adjust the COT control setting CS. The COT setting circuit 502 may increase, decrease, or maintain the current COT control setting CS, depending on the HiZ time T_{HIZ}. For another example, the decision circuit 504 monitors the HiZ time T_{HIZ} between two successive regulation operations and the COT control setting CS to determine whether to assert the control signal CB_MODE (CB_MODE=1). In this embodiment, the switching regulator 100 leaves the CB mode when the output voltage V_{OUT} drops below the lower reference voltage V_{REFOFFSET} (V_{REFOFFSET}=V_{REF}−OFFSET<V_{REF}). In this embodiment, the decision circuit 504 may include a comparator 506 used for comparing the output voltage V_{OUT} and the reference voltage V_{REFOFFSET}, and deasserts the control signal CB_MODE when a comparator output V_{DROP} indicates that of the output voltage V_{OUT} drops below the reference voltage V_{REFOFFSET} (i.e., CB_MODE=0 if V_{OUT}<V_{REFOFFSET}).

When the CB mode is inactive (i.e., CB_MODE=0), the multiplexer 516 selects a comparator output CMPOUT of the comparator 512 as a control input VDSET of the power switch controller 518. The control input VDSET determines the turn-on time of the high-side power switch UG. Specifically, the control input VDSET controls whether to start one regulation operation of the output voltage V_{OUT}. When the feedback voltage V_{FB} is not lower than the reference voltage V_{REF}, the control input VDSET has a logic low level, and the high-side power switch UG is not turned on. However, when the feedback voltage V_{FB} drops below the reference voltage V_{REF}, the control input VDSET has a logic high level, and the high-side power switch UG is turned on. When the CB mode is active (i.e., CB_MODE=1), the multiplexer 516 selects the fixed clock CLK (e.g., CLK=28uS_CLK being a 35 KHz clock with a 28 us period) as the control input VDSET of the power switch controller 418. Hence, the high-side power switch UG is periodically turned on at a fixed clock rate under the CB mode.

The on-time generator 508 is configured to generate a control input VRST to the power switch controller 418. The control input VRST determines the turn-off time of the high-side power switch UG and the turn-on time of the low-side power switch LG. Specifically, the on-time T_{ON} of the high-side power switch UG is defined by the control input VDSET and the control input VRST. For example, the on-time generator 508 may include a current source 520, multiple capacitors (e.g., C1, C2, and C3), multiple switches (e.g., SW1 and SW2), and a comparator 522. The current source 520 provides a reference current α(V_{IN}−V_{OUT}). The ON/OFF state of each of the switches SW1 and SW2 is controlled by the COT control setting CS. When the COT control setting CS is set by a maximum COT control value, both of the switches SW1 and SW2 are turned on, resulting in a longest charge time of the voltage V_{C}. When the COT control setting CS is set by a minimum COT control value, both of the switches SW1 and SW2 are turned off, resulting in a shortest charge time of the voltage V_{C}. When the COT control setting CS is set by a medium COT control value, only one of the switches SW1 and SW2 is turned on, resulting in a medium charge time of the voltage V_{C}. When the voltage V_{C} is lower than a reference voltage VREF_CIP, the control input VRST has a logic high level, the high-side power switch UG is not turned off, and the low-side power switch LG is not turned on. However, when the voltage V_{C} increases above the reference voltage VREF_CIP, the control input VRST has a logic low level, the high-side power switch UG is turned off, and the low-side power switch LG is turned on.

When the CB mode is inactive (i.e., CB_MODE=0), the multiplexer 514 selects a comparator output ZX of the comparator 510 as a control input ZX S of the power switch controller 518. The control input ZX S determines the turn-off time of the low-side power switch LG. The comparator 410 compares the voltage V_{LX} and the ground voltage GND to set the comparator output ZX. When the voltage V_{LX} reaches the ground voltage GND, the comparator output ZX is set to indicate that the low-side power switch LG should be turned off, resulting in a zero inductor current (i.e., I_{L}=0 mA). When the CB mode is active (i.e., CB_MODE=1), the multiplexer 514 selects the comparator output CMPOUT of the comparator 512 as the control input ZX S of the power switch controller 518. When the output voltage V_{OUT} drops below the reference voltage V_{REF}, the comparator output COMOUT is set to indicate that the low-side power switch LG should be turned off, resulting in a negative peak current I_{NEG}.

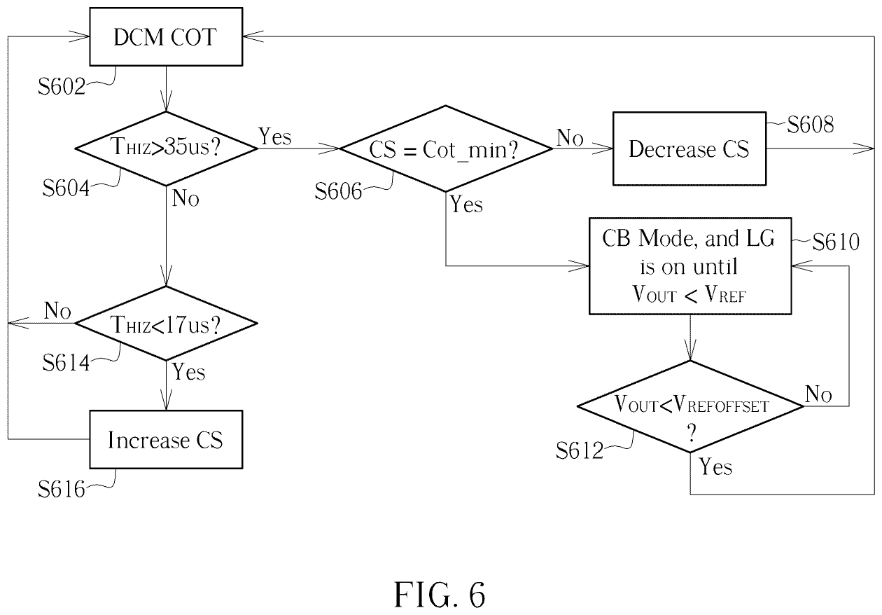

Please refer to FIG. 5 in conjunction with FIG. 6. FIG. 6 is a flowchart illustrating a method for controlling a switching regulator according to an embodiment of the present invention. For example, the method may be employed by the controller circuit 500 shown in FIG. 5. Provided that the result is substantially the same, the steps are not required to be executed in the exact order shown in FIG. 6. In step S602, the controller circuit 500 performs ACOT control under DCM. In step S604, the decision circuit 504 checks if the HiZ time T_{HIZ} between the previous regulation operation and the current regulation operation is longer than a threshold value TH1 (e.g., TH1=35 us). If the HiZ time T_{HIZ} has lasted for a duration exceeding the threshold value TH1 (e.g., TH1=35 us), meaning that the switching frequency F_{SW} is close to an upper bound of the audio frequency band, the decision circuit 504 checks if the COT control setting CS is assigned the minimum COT control value Cot_min (step S606). If the COT control setting CS is not yet assigned the minimum COT control value Cot_min, the decision circuit 504 instructs the COT setting circuit 502 to decrease the COT control setting CS for decreasing the on-time T_{ON} of the high-side power switch UG as well as the positive peak current Iₚₑₐₖ in the current regulation operation (step S608). If the COT control setting CS is assigned the minimum COT control value Cot_min, the decision circuit 504 asserts the control signal CB_MODE (CB_MODE=1) to enable the CB control scheme (i.e., CB mode). In step S610, the regulation operation of the output voltage V_{OUT} is periodically triggered by the fixed clock CLK (e.g., CLK=28uS_CLK).

The CB-mode regulation operation includes a first phase, a second phase, and a third phase. During the first phase, the high-side power switch UG is turned on by the fixed clock CLK (e.g., CLK=28uS_CLK), and the low-side power switch LG is turned off. During the second phase, the high-side power switch UG is turned off when the on-time T_{ON} (which is set by the minimum COT control value Cot_min) expires, and the low-side power switch LG is turned on, where the low-side power switch LG is not turned off until the output voltage V_{OUT} reaches the reference voltage V_{REF}, and the negative peak current I_{NEG} is generated at the time the output voltage V_{OUT} reaches the reference voltage V_{REF}. During the third phase, both of the high-side power switch UG and the low-side power switch LG are turned off, and the negative inductor current flows back to the power source (e.g., battery) through the body diode 106 of the high-side power switch UG, thereby returning the excess energy to the power source (e.g., battery).

In step S612, the decision circuit 504 checks if the output voltage V_{OUT} drops below a lower reference voltage V_{REFOFFSET} (V_{REFOFFSET}<V_{REF}) before a next CB-mode regulation operation is triggered by the fixed clock CLK (e.g., CLK=28uS_CLK). If the output voltage V_{OUT} does not drop below the lower reference voltage V_{REFOFFSET}, the switching regulator 100 keeps operating under the CB mode (step S610). If the output voltage V_{OUT} drops below the lower reference voltage V_{REFOFFSET}, meaning that the load device suddenly becomes a heavy load requiring large power, the decision circuit 504 deasserts the control signal CB_MODE (CB_MODE=0) to disable the CB control scheme (i.e., CB mode), and the flow proceeds to step S602. In other words, the switching regulator 100 leaves the CB mode, and re-enters the normal mode (e.g., ACOT control under DCM).

If step S604 judges that the HiZ time T_{HIZ} between the previous regulation operation and the current regulation operation (i.e., a duration of the HiZ state that has lasted since an end of the previous regulation operation) is not longer than the threshold value TH1 (e.g., TH1=35 uS), the flow proceeds to step S614. In step S614, the decision circuit 504 checks if the HiZ time T_{HIZ} between the previous regulation operation and the current regulation operation (i.e., a duration of the HiZ state that has lasted since an end of the previous regulation operation) is shorter than a threshold value TH2 (e.g., TH2=17 us). If the HiZ time T_{HIZ} is not shorter than the threshold value TH2 (e.g., TH2=17 us), implying that the HiZ time T_{HIZ} is between the threshold values TH1 and TH2, the COT setting circuit 502 maintains the current COT control setting CS unchanged, and the high-side power switch UG has the same on-time T_{ON} in the current regulation operation. If the HiZ time T_{HIZ} is shorter than the threshold value TH2 (e.g., TH2=17 us), the decision circuit 504 instructs the COT setting circuit 502 to increase the COT control setting CS for increasing the on-time T_{ON} of the high-side power switch UG as well as the positive peak current Iₚₑₐₖ in the current regulation operation (step S616).

As shown in FIG. 6, the ACOT control scheme 110 decreases the COT control setting CS (i.e., on-time T_{ON}) when the condition T_{HIZ}>35 us is met, increases the COT control setting CS (i.e., on-time T_{ON}) when the condition T_{HIZ}<17 us is met, and maintains the current COT control setting CS (i.e., on-time T_{ON}) when the condition 17 us≤T_{HIZ}≤35 us is met; a transition from the ACOT control scheme 110 to the CB control scheme 112 is triggered when conditions T_{HIZ}>35 us and CS=Cot_min are both met; and a transition from the CB control scheme 112 to the ACOT control scheme 110 is triggered when the condition V_{OUT}<V_{REFOFFSET} is met. The COT control setting CS employed by the ACOT control scheme 110 may support a plurality of COT control values. The ACOT control scheme 110 has hysteresis in changing the COT control setting CS (positive peak current Iₚₑₐₖ) to prevent frequent switching between two COT control values. In other words, a triggering condition for switching a first COT control value to a second COT control value is different from a triggering condition for switching the second COT control value back to the first COT control value. Similarly, the transition between the ACOT control scheme 110 and the CB control scheme 112 also has hysteresis to prevent frequent switching between two control schemes. In other words, a triggering condition for switching the ACOT control scheme 110 to the CB control scheme 112 is different from a triggering condition for switching the CB control scheme 112 back to the ACOT control scheme 110.

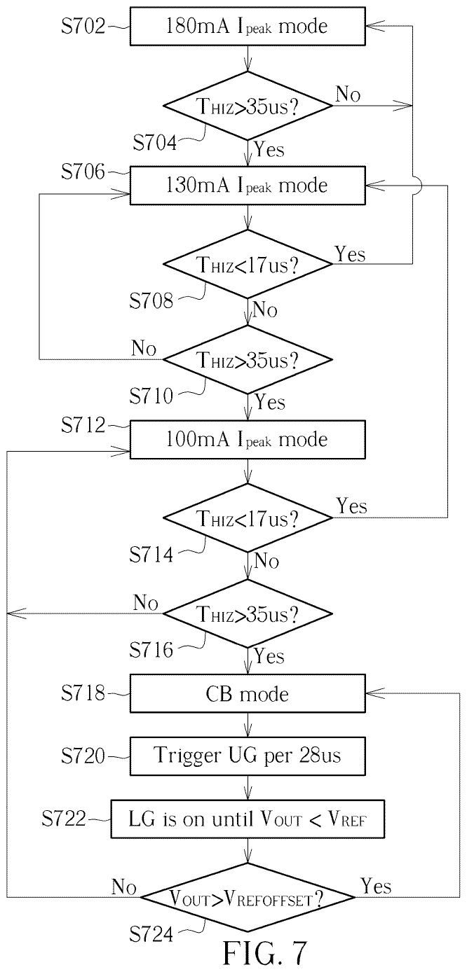

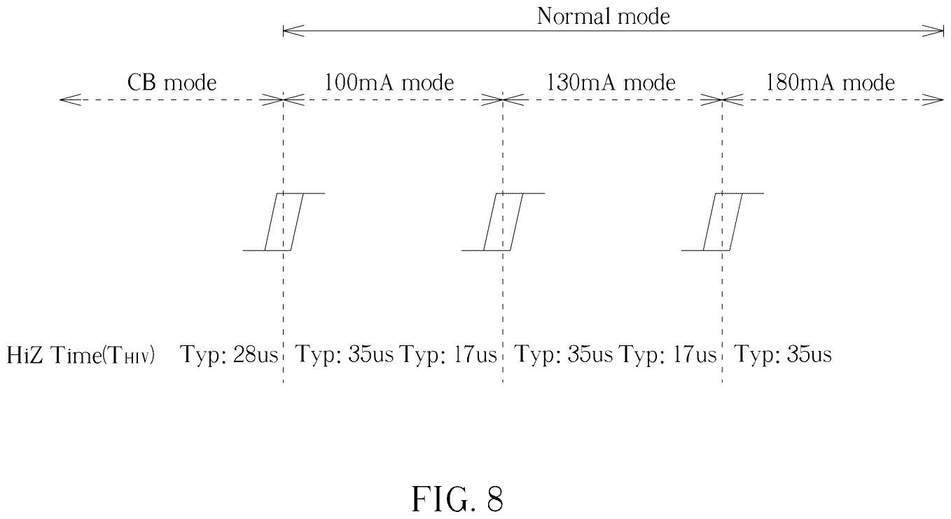

Please refer to FIG. 7 in conjunction with FIG. 8. FIG. 7 is a flowchart illustrating a hysteresis-based control method for controlling V_{OUT} regulation according to an embodiment of the present invention. FIG. 8 is a diagram illustrating a hysteresis behavior of a switching regulator according to an embodiment of the present invention. For brevity and simplicity, the following assumes that the ACOT control scheme supports three COT control values Cot_max, Cot med, Cot_min, where the COT control value Cot_max is a default value defining a maximum on-time T_{ON} for achieving an 180 mA Iₚₑₐₖ, the COT control value Cot_med (Cot_med<Cot_max) defines a medium on-time T_{ON} for achieving an 130 mA Iₚₑₐₖ, and the COT control value Cot_min (Cot_min<Cot_med) defines a minimum on-time T_{ON} for achieving an 100 mA Iₚₑₐₖ.

Initially, the ACOT control scheme 110 selects the default value (i.e., Cot_max), and operates under the 180 mA Iₚₑₐₖ mode (step S702). When the ACOT control scheme 110 operates under the 180 mA Iₚₑₐₖ mode, the HiZ time T_{HIZ} is checked to determine if it is longer than the threshold value TH1 (e.g., TH1=35 us) (step S704). When the HiZ time T_{HIZ} is longer than the threshold value TH1 (e.g., TH1=35 us), the ACOT control scheme 110 selects the COT control value Cot_med, and switches from the 180 mA Iₚₑₐₖ mode to the 130 mA Iₚₑₐₖ mode (step S706). When the HiZ time T_{HIZ} is not longer than the threshold value TH1 (e.g., TH1=35 us), the ACOT control scheme 110 keeps operating under the 180 mA Iₚₑₐₖ mode (step S702).

When the ACOT control scheme 110 operates under the 130 mA Iₚₑₐₖ mode, the HiZ time T_{HIZ} is checked to determine if it is shorter than a threshold value TH2 (e.g., TH2=17 us) (step S708), and/or determine if it is longer than the threshold value TH1 (e.g., TH1=35 us) (step S710). When the HiZ time T_{HIZ} is shorter than the threshold value TH2 (e.g., TH2=17 us), the ACOT control scheme 110 selects the COT control value Cot_max, and switches from the 130 mA Iₚₑₐₖ mode to the 180 mA Iₚₑₐₖ mode (step S702). When the HiZ time T_{HIZ} is longer than the threshold value TH1 (e.g., TH1=35 us), the ACOT control scheme 110 selects the COT control value Cot_min, and switches from the 130 mA Iₚₑₐₖ mode to the 100 mA Iₚₑₐₖ mode (step S712). When the HiZ time T_{HIZ} is between the threshold values TH1 and TH2, the ACOT control scheme 110 keeps operating under the 130 mA Iₚₑₐₖ mode (step S706).

When the ACOT control scheme 110 operates under the 100 mA Iₚₑₐₖ mode, the HiZ time T_{HIZ} is checked to determine if it is shorter than the threshold value TH2 (e.g., TH2=17 us) (step S714), and/or determine if it is longer than the threshold value TH1 (e.g., TH1=35 us) (step S716). When the HiZ time T_{HIZ} is shorter than the threshold value TH2 (e.g., TH2=17 us), the ACOT control scheme 110 selects the COT control value Cot_med, and switches from the 100 mA Iₚₑₐₖ mode to the 130 mA Iₚₑₐₖ mode (step S706). When the HiZ time T_{HIZ} is longer than the threshold value TH1 (e.g., TH1=35 us), the CB control scheme 112 is enabled (step S718). When the HiZ time T_{HIZ} is between the threshold values TH1 and TH2, the ACOT control scheme 110 keeps operating under the 100 mA Iₚₑₐₖ mode (step S712).

When the ACOT control scheme 110 operates under the CB mode, the regulation operation of the output voltage V_{OUT} is periodically triggered by the fixed clock CLK (e.g., CLK=28uS_CLK), and the low-side power switch LG is turned off at the time the output voltage V_{OUT} drops below the reference voltage V_{REF} (steps S720 and S722). In step S724, the output voltage V_{OUT} is checked to determine if it drops below the lower reference voltage V_{REFOFFSET}. When the output voltage V_{OUT} reaches the lower reference voltage V_{REFOFFSET}, the CB control scheme 112 is disabled, and the flow proceeds to step S712 in which the ACOT control scheme operates under the 100 mA Iₚₑₐₖ mode.

The foregoing outlines the features of several embodiments, enabling those skilled in the art to fully appreciate the aspects of the present disclosure. Those skilled in the art should recognize that the present disclosure provides a foundation for designing or modifying other processes and structures to achieve substantially the same functions and/or substantially the same results as those of the embodiments introduced herein. Furthermore, such equivalent arrangements do not deviate from the spirit and scope of the present disclosure, and various changes, substitutions, and alterations may be made without so departing.

What is claimed is:

1. A controller circuit of a switching regulator, comprising:
a constant on-time (COT) setting circuit, configured to adaptively adjust a COT control setting, wherein an on-time of a high-side power switch of the switching regulator depends on the COT control setting; and
a decision circuit, configured to enable a control scheme of periodically triggering a regulation operation of an output voltage of the switching regulator during a period in which the COT control setting is assigned a minimum COT control value allowed by the switching regulator, wherein during the period, a turn-off time of a low-side power switch of the switching regulator depends on a comparison between a feedback voltage and a first reference voltage, where the feedback voltage is derived from the output voltage.

2. The controller circuit of claim 1, wherein the decision circuit is further configured to check if a High-Z (HiZ) time between a previous regulation operation and a current regulation operation is longer than a threshold value, and check if the COT control setting is assigned the minimum COT control value; and when the HiZ time is longer than the threshold value and the COT control setting is assigned the minimum COT control value, the decision circuit is configured to enable the control scheme.

3. The controller circuit of claim 1, wherein the decision circuit is further configured to compare the feedback voltage and a second reference voltage that is lower than the first reference voltage; and when the feedback voltage reaches the second reference voltage during the period, the decision circuit is further configured to disable the control scheme.

4. The controller circuit of claim 1, wherein the decision circuit is further configured to check if a High-Z (HiZ) time between a previous regulation operation and a current regulation operation is longer than a threshold value, and check if the COT control setting is assigned the minimum COT control value; and when the HiZ time is longer than the threshold value and the COT control setting is not yet assigned the minimum COT control value, the decision circuit is further configured to instruct the COT setting circuit to decrease the COT control setting.

5. The controller circuit of claim 1, wherein the decision circuit is further configured to check if a High-Z (HiZ) time between a previous regulation operation and a current regulation operation is longer than a first threshold value, and check if the HiZ time between the previous regulation operation and the current regulation operation is shorter than a second threshold value; and when the HiZ time is not longer than the first threshold value and is not shorter than the second threshold value, the COT setting circuit is configured to maintain the COT control setting unchanged.

6. The controller circuit of claim 1, wherein the decision circuit is further configured to check if a High-Z (HiZ) time between a previous regulation operation and a current regulation operation is shorter than a threshold value; and when the HiZ time is shorter than the threshold value, the decision circuit is further configured to instruct the COT setting circuit to increase the COT control setting.

7. A method of controlling a switching regulator, comprising:
adaptively adjusting a constant on-time (COT) setting, wherein an on-time of a high-side power switch of the switching regulator depends on the COT control setting; and
during a period in which the COT control setting is assigned a minimum COT control value allowed by the switching regulator, enabling a control scheme of periodically triggering a regulation operation of an output voltage of the switching regulator, wherein during the period, a turn-off time of a low-side power switch of the switching regulator depends on a comparison between a feedback voltage and a first reference voltage, where the feedback voltage is derived from the output voltage.

8. The method of claim 7, further comprising:
checking if a High-Z (HiZ) time between a previous regulation operation and a current regulation operation is longer than a threshold value; and
checking if the COT control setting is assigned the minimum COT control value;
wherein enabling the control scheme of periodically triggering the regulation operation of the output voltage of the switching regulator comprises:
in response to the HiZ time being longer than the threshold value and the COT control setting being assigned the minimum COT control value, enabling the control scheme.

9. The method of claim 7, further comprising:
comparing the feedback voltage and a second reference voltage that is lower than the first reference voltage; and
in response to the feedback voltage reaching the second reference voltage during the period, disabling the control scheme.

10. The method of claim 7, wherein the decision circuit is further configured to check if a High-Z (HiZ) time between a previous regulation operation and a current regulation operation is longer than a threshold value, and check if the COT control setting is assigned the minimum COT control value; and when the HiZ time is longer than the threshold value and the COT control setting is not yet assigned the minimum COT control value, the decision circuit is further configured to instruct the COT setting circuit to decrease the COT control setting.

11. The method of claim 7, further comprising:
checking if a High-Z (HiZ) time between a previous regulation operation and a current regulation operation is longer than a first threshold value;
checking if the HiZ time between the previous regulation operation and the current regulation operation is shorter than a second threshold value; and
in response to the HiZ time being not longer than the first threshold value and being not shorter than the second threshold value, maintaining the COT control setting unchanged.

12. The method of claim 7, further comprising:
checking if a High-Z (HiZ) time between a previous regulation operation and a current regulation operation is shorter than a threshold value; and
in response to the HiZ time being shorter than the threshold value, increasing the COT control setting.
